(19) United States
(12) Patent Application Publication
(10) Pub. No.: US 2011/0156067 A1
(43) Pub. Date: Jun. 30, 2011

(54) LIGHT EMITTING MODULE AND ILLUMINATION DEVICE WITH THE SAME

(75) Inventors: Jhih-Han Lin, Hsinchu (TW); Tsung-Lin Yu, Hsinchu (TW); He-Shun Yang, Hsinchu (TW); Meng-Chai Wu, Hsinchu (TW)

(73) Assignee: Lextar Electronics Corporation, Hsinchu (TW)

(21) Appl. No.: 12/981,868

(22) Filed: Dec. 30, 2010

(30) Foreign Application Priority Data
Dec. 31, 2009 (TW) 098146261

(51) Int. Cl. H01L 33/62; H01L 33/08

(52) U.S. Cl. 257/91; 257/88; 257/E33.005; 257/E33.066

(57) ABSTRACT

A light emitting module includes a substrate, a conductive layer, a first light emitter, a second light emitter and a protection layer. The substrate has a first surface and a second surface on opposite sides of the substrate. The conductive layer is configured in the substrate. The first light emitter is disposed on the first surface and connected with the conductive layer. The second light emitter is disposed on the second surface and connected with the conductive layer. The protection layer covers the first light emitter and the second light emitter.

### FIELD OF THE INVENTION

The present invention relates to a light emitting module, and more particularly to a light emitting module with wide light illuminating range.

### BACKGROUND OF THE INVENTION

Recently, various light emitting modules are widely used in daily life, and many of them have light-emitting diodes.

Generally, in the light emitting modules, the light-emitting diodes are installed on a printed circuit board (PCB). Referring to FIGS. 1 to 3, a light emitting module 10 includes a printed circuit board 12, a plurality of light emitting diodes 14 and a waterproof glue 16. The light emitting diodes 14 are configured on the printed circuit board 12. The waterproof glue 16 covers the printed circuit board 12 and the light emitting diodes 14, so that the printed circuit board 12 and the light emitting diodes 14 can be protected from damage caused by the environmental factors.

However, the light is emitted from a single side of the printed circuit board 12, and there is no light emitted from another side of the printed circuit board 12 in the conventional light emitting module 10. With comparison to the traditional fluorescent lamp, the light illuminating range of the light emitting module 10 is smaller. Therefore, the application of the light emitting module 10 would be limited.

Therefore, how to overcome the shortcomings mentioned above is an important issue of this industry.

### SUMMARY OF THE INVENTION

Therefore, the object of the present invention is to provide a light emitting module.

The present invention provides a light emitting module, which includes a substrate, a conductive layer, a first light emitter, a second light emitter and a protection layer. The substrate has a first surface and a second surface on opposite sides of the substrate. The conductive layer is configured in the substrate. The first light emitter is disposed on the first surface and connected with the conductive layer. The second light emitter is disposed on the second surface and connected with the conductive layer. The protection layer covers the first light emitter and the second light emitter.

In the above light emitting module, the first light emitter and the second light emitter are respectively disposed on the first surface and the second surface, therefore the light of the light emitting module can be emitted out from the two sides of the substrate. Consequently, the light illuminating range of the light emitting module can be increased, and the application of the light emitting module can be expanded.

### BRIEF DESCRIPTION OF THE DRAWINGS

The above objects and advantages of the present invention will become more readily apparent to those ordinarily skilled in the art after reviewing the following detailed description and accompanying drawings, in which:

FIG. 1 is an isometric schematic view of a conventional light emitting module.

FIG. 2 is a side cross-sectional schematic view of the light emitting module of FIG. 1, taken along line II-II′ thereof.

FIG. 3 is a partial side cross-sectional schematic view of the light emitting module of FIG. 1, taken along line III-III′ thereof.

FIG. 4 is an isometric schematic view of a light emitting module according to an embodiment of the present invention.

FIG. 4A is a side cross-sectional schematic view of the light emitting module of FIG. 4, taken along line X-X′ thereof.

FIG. 5A is a side cross-sectional schematic view of the light emitting module of FIG. 4, taken along line V-V′ thereof.

FIG. 5B is an isometric schematic view of a light emitting module according to another embodiment of the present invention.

FIG. 6A is a schematic view of light emitting direction of a first light emitter and a second light emitter of the light emitting module of FIG. 4.

FIGS. 6B and 6C are schematic views of the light emitting direction of the first light emitter and the second light emitter of the light emitting module according to other embodiments of the present invention.

FIG. 7A is a schematic view of circuits in a conductive layer of the light emitting module of FIG. 4.

FIGS. 7B to 7G are schematic views of the circuits in the conductive layers of the light emitting modules according to other embodiments of the present invention.

FIGS. 8A to 8C are schematic views of the light emitting direction of the first light emitter, the second light emitter and the third light emitter of the light emitting module according to other embodiments of the present invention.

FIGS. 9A to 9D are schematic views of the light emitting direction of the first light emitter, the second light emitter, the third light emitter and the fourth light emitter of the light emitting module according to other embodiments of the present invention.

FIG. 10 is an isometric schematic view of an illumination device according to an embodiment of the present invention.

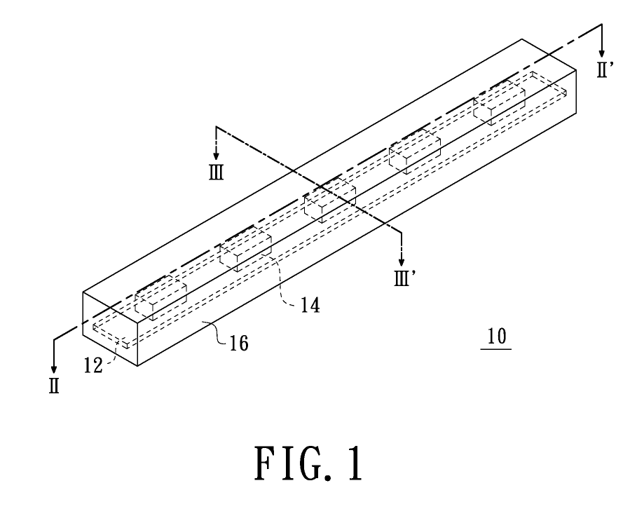

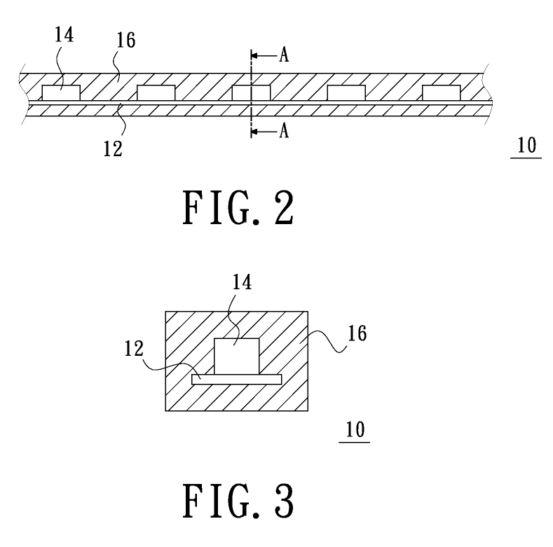

### DETAILED DESCRIPTION OF PREFERRED EMBODIMENTS

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

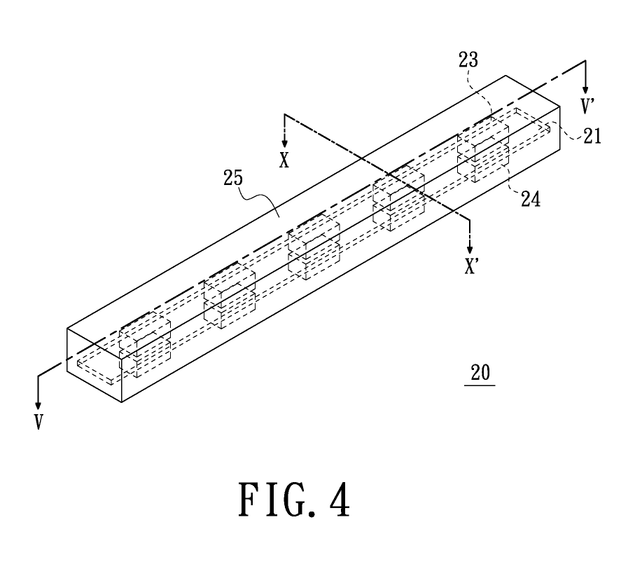

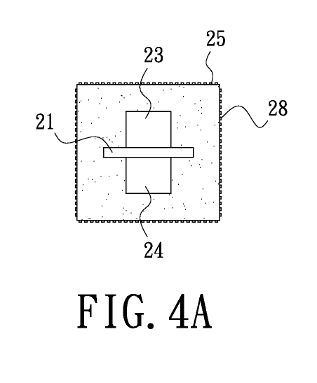

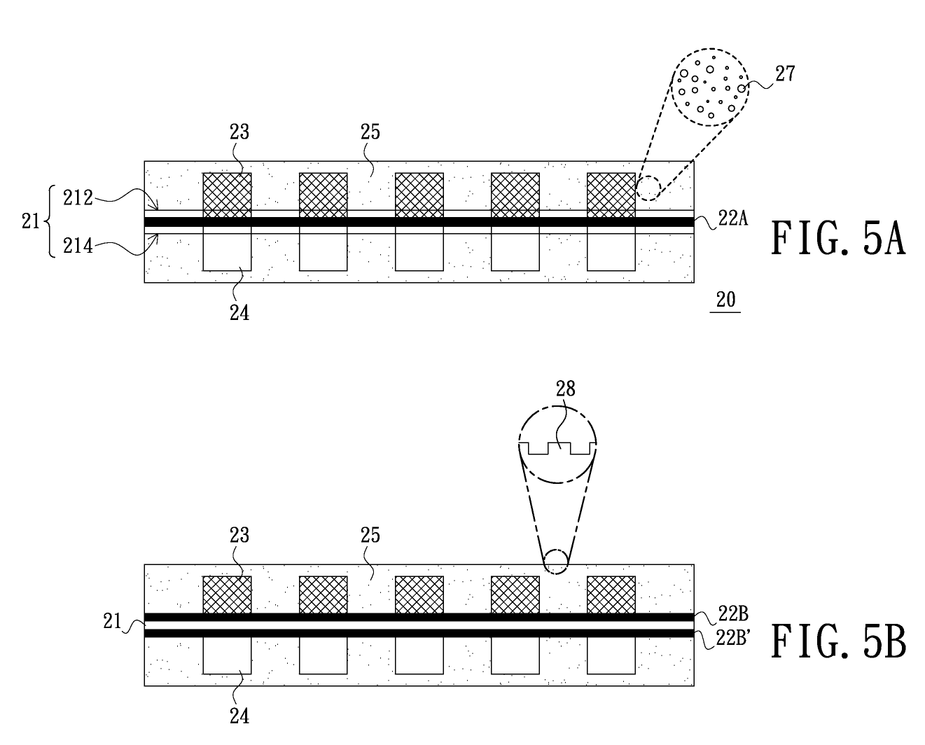

FIG. 4 is an isometric schematic view of a light emitting module according to an embodiment of the present invention. FIG. 4A is a side cross-sectional schematic view of the light emitting module of FIG. 4, taken along line X-X′ thereof. FIG. 5A is a side cross-sectional schematic view of the light emitting module of FIG. 4, taken along line V-V′ thereof. Referring to FIGS. 4 to 5A, the light emitting module 20 includes a substrate 21, a conductive layer 22A, a first light emitter 23, a second light emitter 24 and a protection layer 25. The substrate 21 has a first surface 212 and a second surface 214 on opposite sides of the substrate 21. The conductive layer 22A is configured in the substrate 21. The first light emitter 23 is disposed on the first surface 212 and electrically connected with the conductive layer 22A. The second light emitter 24 is disposed on second surface 214 and electrically connected with the conductive layer 22A. The protection layer 25 covers the first light emitter 23 and the second light emitter 24.

The first light emitter 23 and the second light emitter 24 are respectively disposed on the first surface 212 and the second surface 214, therefore the light of the light emitting module 20 can be emitted out from the two sides of the substrate 21. Consequently, the light illuminating range of the light emitting module 20 can be increased, and the application of the light emitting module 20 can be expanded. Furthermore, because the first light emitter 23 and the second light emitter 24 are both disposed on the substrate 21, material cost of the light emitting module 20 can be saved.

In details, the substrate 21 can be an insulating substrate, a flexible substrate, an aluminum composite substrate or a ceramic substrate. In the embodiment, the substrate 21 is the flexible substrate. The conductive layer 22A is located inside the substrate 21. In another embodiment, referring to FIG. 5B, the substrate 21 is the ceramic substrate, and the conductive layer 22B, 22B′ can be located on two surfaces of the substrate 21.

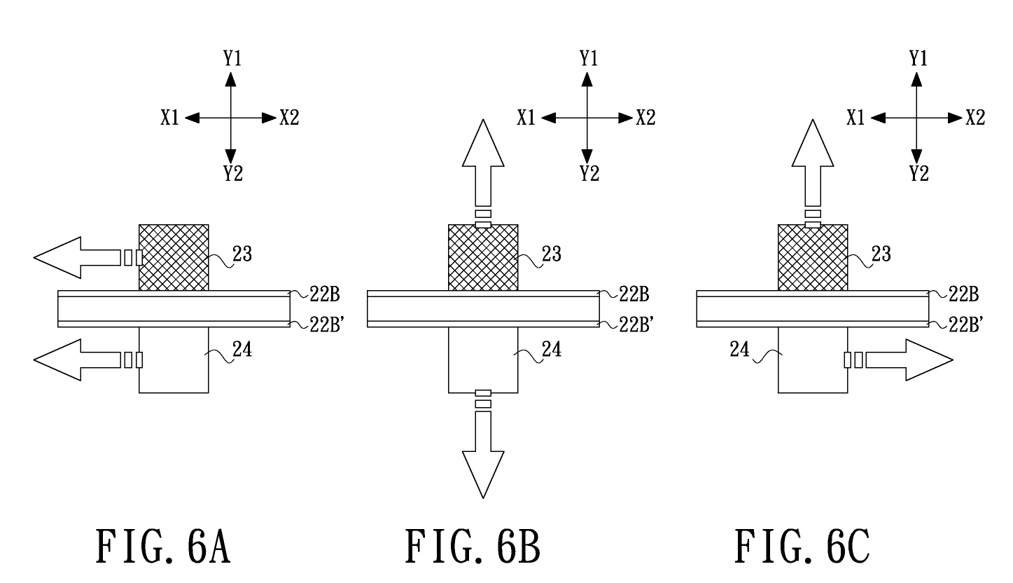

In the embodiment, the first light emitter 23 can include at least one first light emitting diode element, and the second light emitter 24 can include at least one second light emitting diode element. The first light emitting diode element or the second light emitting diode element can be a surface mounted device or a lamp. The light emitting direction of the first light emitting diode element or the second light emitting diode element can be the same or not exactly the same with each other. The light emitting direction of the first light emitter 23 and the second light emitter 24 would be indicated by arrows in FIGS. 6A to 6C. Referring to FIG. 6A, the light emitting direction of the first light emitter 23 and the second light emitter 24 is the same and along the direction X1. Referring to FIG. 6B, the light emitting direction of the first light emitter 23 is different with that of the second light emitter 24, and the light emitting direction of the first light emitter 23 is along the direction Y1, and the light emitting direction of the second light emitter 24 is along the direction Y2. Referring to FIG. 6C, the light emitting direction of the first light emitter 23 is different with that of the second light emitter 24, and the light emitting direction of the first light emitter 23 is along the direction Y1, and the light emitting direction of the second light emitter 24 is along the direction X2.

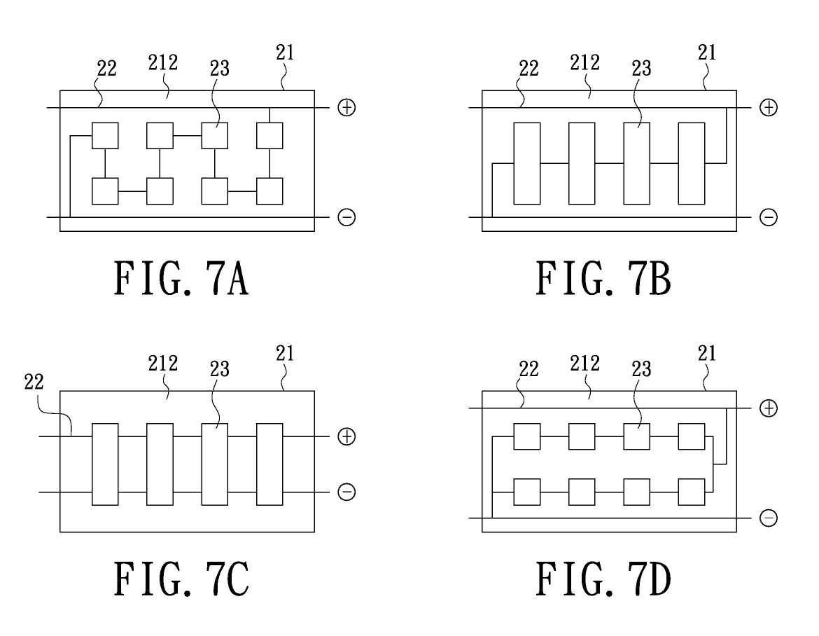

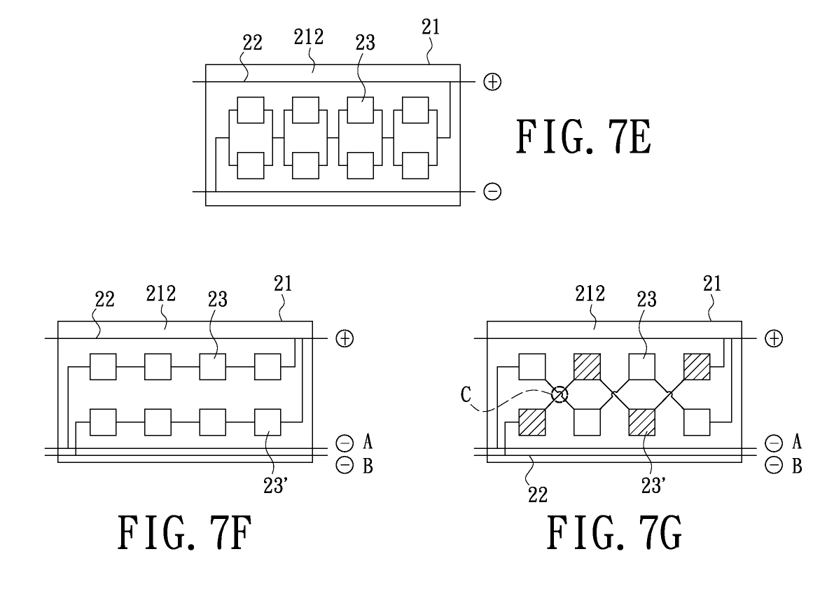

FIGS. 7A and 7G are schematic views of circuits in the conductive layers of the light emitting modules according to the embodiments of the present invention, which show the top views of the light emitting modules seeing from first surface 212 of the substrate 21. The conductive layer 22 can include at least one circuit corresponding to the first light emitter 23 and the second light emitter 24. The at least one circuit can be used to provide driving signals for the first light emitter 23 and the second light emitter 24. If there is a plurality of the circuits in the conductive layer 22, the first light emitter 23 and the second light emitter 24 can be driven asynchronously.

Referring to FIG. 7A, the first light emitting diode elements of the first light emitter 23 are arranged in two rows, and are electrically connected in series.

In other embodiments, there are different layouts of the circuits according to various requirements, and the first light emitting diode elements of the first light emitter 23 can be electrically connected in series or in parallel in other forms. For example, referring to FIG. 7B, the first light emitting diode elements of the first light emitter 23 are arranged in a row, and are electrically connected in series. Referring to FIG. 7C, the first light emitting diode elements of the first light emitter 23 are arranged in a row, and are electrically connected in parallel. Referring to FIG. 7D, the first light emitting diode elements of the first light emitter 23 are arranged in two rows, the first light emitting diode elements of the first light emitter 23 in each row are electrically connected in series to form a unit, and the two units are electrically connected in parallel. Referring to FIG. 7E, two of the first light emitting diode elements of the first light emitter 23 are electrically connected in parallel to form a unit, and then the units of the two the first light emitting diode elements are electrically connected in series. Referring to FIG. 7F, the first light emitting diode elements of the first light emitter 23 are arranged in two rows, the first light emitting diode elements of the first light emitters 23, 23′ in each row are electrically connected in series to form a unit, the two units are electrically connected in parallel with the same positive electrode and electrically connected with different negative electrodes A, B. Referring to FIG. 7G, the first light emitting diode elements of the first light emitter s23, 23′ form two series connected circuits, the two series connected circuits are arranged in zigzag shape, and the conductive layer 22 has at least a cross connection region C, and the two series connected circuits are electrically connected with the same positive electrode and electrically connected with different negative electrodes A, B.

In the embodiments of FIGS. 7F and 7G, the two series connected circuits are electrically connected with the different negative electrodes A, B, so that the first light emitters 23, 23′ can be driven by different driving signals to emit light asynchronously. For example, if the current driving signal is provided by the negative electrode A, the first light emitter 23 would emit the light and the first light emitter 23′ would not emit the light. If the current driving signal is provided by the negative electrode B, the first light emitter 23′ would emit the light and the first light emitter 23 would not emit the light.

In the above embodiments, that the first light emitters 23, 23′ are disposed on the first surface 212 of the substrate 21 is described for exemplary purposes, the present invention is not limited herein, and the connection structure of the second light emitters on the second surface of the substrate and the circuit of the conductive layer can be similar to that of the first light emitters 23, 23′ and the circuit.

The protection layer 25 can include an insulating layer or a transparent layer. The protection layer 25 is used to protect the first light emitter 23 and the second light emitter 24 from damage caused by the environmental factors. Specially, to make the light generated by the first light emitter 2 and the second light emitter 24 diffuse along different directions, the protection layer 25 can include a plurality of light diffusing particles 27 dispersed therein, as shown in FIG. 5A. The light diffusing particles 27 may diffuse the light generated by the first light emitter 23 and the second light emitter 24.

Referring to FIGS. 4A and 5B, to prevent the light from total reflection at the protection layer 25, the protection layer 25 can include a plurality of micro-structures 28 formed on a surface thereof. The micro-structures 28 can be arranged regularly, irregularly, continuously or discontinuously and extended along an optional direction, and cross sections of the micro-structures 28 can be arc-shaped, rectangular, triangular or polygonal. Referring to FIG. 4A, the micro-structures 28 are irregular concave/convex structures that are arranged continuously and regularly and extended along V-V′ direction in FIG. 4. Referring to FIG. 5B, the micro-structures 28 are extended along X-X′ direction in FIG. 4.

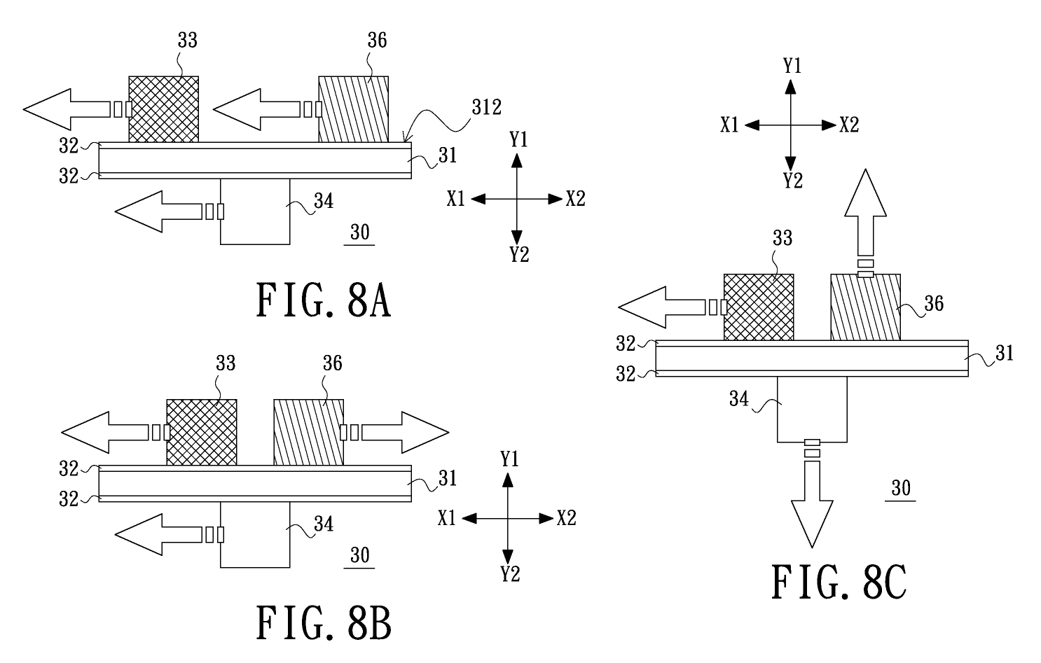

Referring to FIG. 8A, to further expand the application of the light emitting module 30, the light emitting module 30 can include a third light emitter 36. The third light emitter 36 is disposed on the first surface 312 of the substrate 31. The third light emitter 36 can includes a plurality of third light emitting diode elements. The third light emitter 36 can be a surface mounted device or a lamp. Corresponding to the third light emitter 36, the conductive layer 32 can include a plurality of circuits used to provide driving signals for the third light emitter 36. In the embodiment, the light emitting direction of the first light emitter 33, the second emitter 34 and the third light emitter 36 are the same and along the direction X1. The first light emitter 33 and the third light emitter 36 can be arranged on the first surface 312 irregularly. For example, the first light emitter 33 and the third light emitter 36 are spaced from each other, so that the luminous efficiency of the first light emitter 33 and the third light emitter 36 can be improved. It is should be understood that, in other embodiments, the light emitting direction of the first light emitter 33, the second emitter 34 and the third light emitter 36 can be not exactly the same. For example, referring to FIG. 8B, the light emitting direction of the first light emitter 33 and the second light emitter 34 is along the direction X1, and the light emitting direction of the third light emitter 36 is along the direction X2. Referring to FIG. 8C, the light emitting direction of the first light emitter 33 is along the direction X1, the light emitting direction of the second light emitter 34 is along the direction Y2 and the light emitting direction of the third light emitter 36 is along the direction Y1.

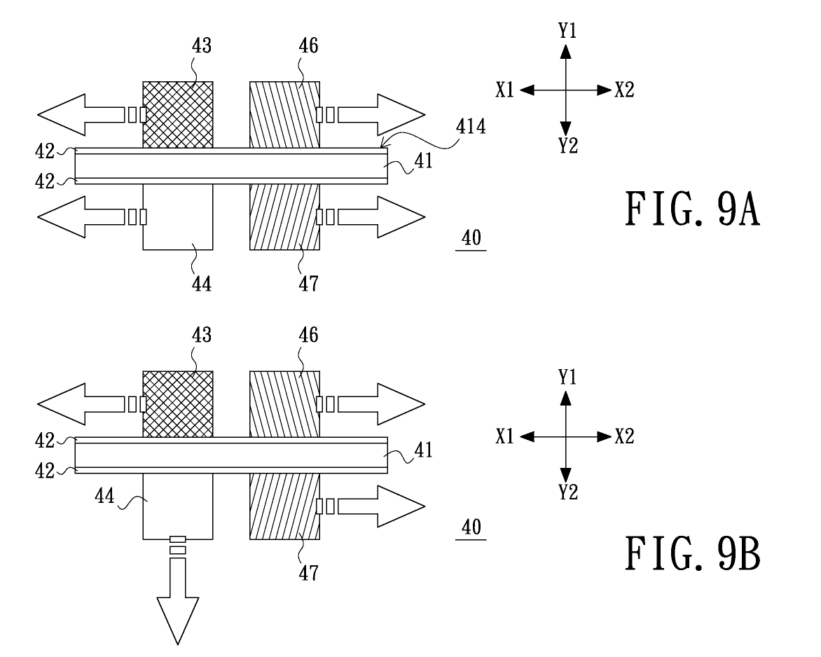

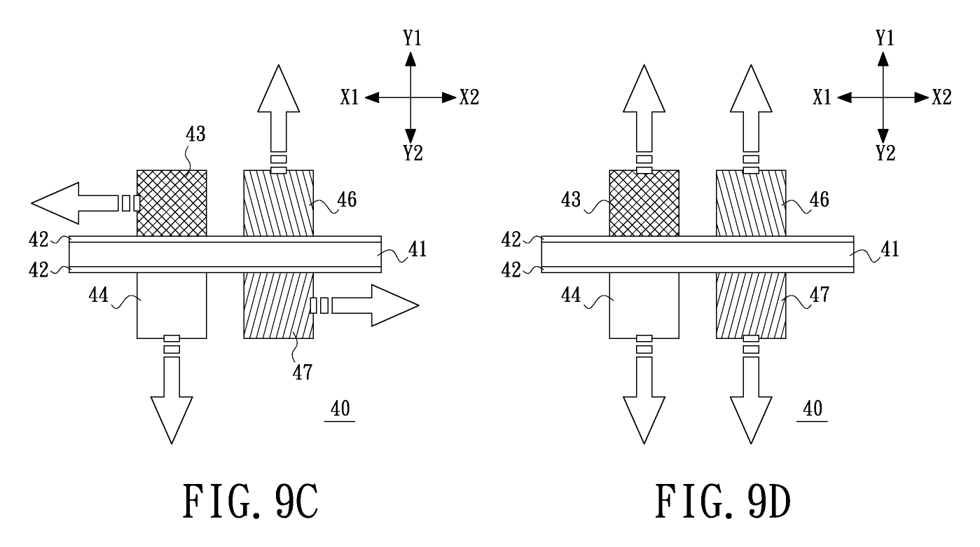

Referring FIG. 9A, in another embodiment, the light emitting module 40 can further include a fourth light emitter 47. The fourth light emitter 47 is disposed on the second surface 414 of the substrate 41. The fourth light emitter 47 can includes a plurality of fourth light emitting diode elements. The fourth light emitter 47 can be a surface mounted device or a lamp. Corresponding to the fourth light emitter 47, the conductive layer 42 can include a plurality of circuits used to provide driving signals for the fourth light emitter 47. Specially, the light emitting direction of the first light emitter 43 and the second light emitter 44 is along the direction X1, and the light emitting direction of the third light emitter 46 and the fourth light emitter 47 is along the direction X2.

It should be understood that, in other embodiments, the light emitting direction of the first light emitter 43, the second light emitter 44, the third light emitter 46 and the fourth light emitter 47 can be the same or different. For example, referring to FIG. 9B, the light emitting direction of the first light emitter 43 is along the direction X1, the light emitting direction of the second light emitter 44 is along the direction Y2, and the light emitting direction of the third light emitter 46 and the fourth light emitter 47 is along the direction X2. Referring to FIG. 9C, the light emitting direction of the first light emitter 43 is along the direction X1, the light emitting direction of the second light emitter 44 is along the direction Y2, the light emitting direction of the third light emitter 46 is along direction Y1, and the light emitting direction of the fourth light emitter 47 is along the direction X2. Referring to FIG. 9D, the light emitting direction of the first light emitter 43 and the third light emitter 46 is along the direction Y1, and the light emitting direction of the second light emitter 44 and the fourth light emitter 47 is along the direction Y2.

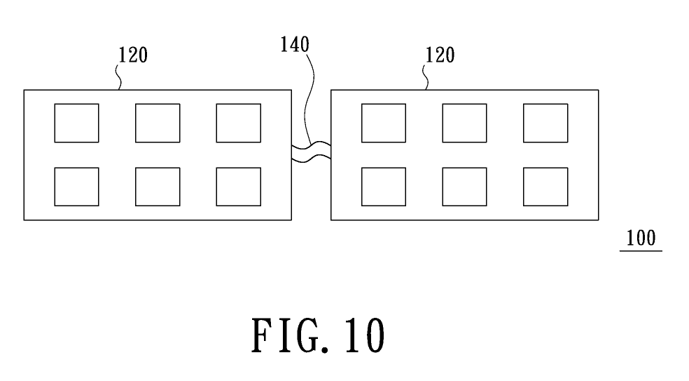

The light emitting modules are described in the above embodiments independently. It should be understood that the light emitting modules can be used in other devices. For example, referring to FIG. 10, an illumination device 100 according to an embodiment of the present invention is shown. The illumination device 100 include two light emitting modules 120 and a connecting unit 140 connected with the light emitting modules 120. The light emitting module 120 can be selected from the light emitting modules mentioned in the above embodiments. The connecting unit 140 can be a welding member, a wire, a male and female connector or a latching structure. In the embodiment, the connecting unit 140 is the wire.

In summary, in the light emitting module of the present invention, the first light emitter and the second light emitter are respectively disposed on the first surface and the second surface, therefore the light of the light emitting module can be emitted out from the two sides of the substrate. Consequently, the light illuminating range of the light emitting module can be increased, and the application of the light emitting module can be expanded.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A light emitting module, comprising:
a substrate having a first surface and a second surface on opposite sides of the substrate;
a conductive layer configured in the substrate;
a first light emitter disposed on the first surface and connected with the conductive layer;
a second light emitter disposed on the second surface and connected with the conductive layer; and
a protection layer covering the first light emitter and the second light emitter.

2. The light emitting module according to claim 1, wherein the substrate comprises an insulating substrate, a flexible substrate, an aluminum composite substrate or a ceramic substrate.

3. The light emitting module according to claim 1, wherein light emitting direction of the first light emitter is the same with that of the second light emitter.

4. The light emitting module according to claim 1, wherein light emitting direction of the first light emitter is different with that of the second light emitter.

5. The light emitting module according to claim 1, wherein the first light emitter comprises a plurality of first light emitting diode elements, and the second light emitter comprises a plurality of second light emitting diode elements.

6. The light emitting module according to claim 5, wherein the conductive layer comprises a plurality of circuits corresponding to the first light emitting diode elements and the second light emitting diode elements, and the circuits are adapted to provide driving signals for the first light emitting diode elements and the second light emitting diode elements.

7. The light emitting module according to claim 5, wherein light emitting direction of the first light emitting diode elements are not exactly the same with each other, and light emitting direction of the second light emitting diode elements is not exactly the same with each other.

8. The light emitting module according to claim 1, wherein the protection layer comprises an insulating layer or a transparent layer.

9. The light emitting module according to claim 1, wherein the protection layer comprises a plurality of light diffusing particles dispersed therein.

10. The light emitting module according to claim 1, wherein the protection layer comprises a plurality of micro-structures formed on a surface thereof.

11. The light emitting module according to claim 10, wherein the micro-structures are arranged continuously or discontinuously.

12. The light emitting module according to claim 10, wherein the micro-structures are arranged regularly or irregularly.

13. The light emitting module according to claim 10, wherein cross sections of the micro-structures are arc-shaped, rectangular, triangular or polygonal.

14. The light emitting module according to claim 1, wherein the light emitting module further comprises a third light emitter disposed on the first surface.

15. The light emitting module according to claim 14, wherein the third light emitter comprises a plurality of third light emitting diode elements.

16. The light emitting module according to claim 15, wherein the conductive layer comprises a plurality of circuits corresponding to the third light emitting diode elements, and the circuits are adapted to provide driving signals for the third light emitting diode elements.

17. The light emitting module according to claim 14, wherein light emitting direction of the first light emitter, the second light emitter and the third light emitter is the same with each other.

18. The light emitting module according to claim 14, wherein light emitting direction of the first light emitter, the second light emitter and the third light emitter is not exactly the same with each other.

19. The light emitting module according to claim 14, wherein the light emitting module further comprises a fourth light emitter disposed on the second surface.

20. The light emitting module according to claim 19, wherein the fourth light emitter comprises a plurality of fourth light emitting diode elements.

21. The light emitting module according to claim 20, wherein the conductive layer comprises a plurality of circuits corresponding to the fourth light emitting diode elements, and the circuits are adapted to provide driving signals for the fourth light emitting diode elements.

22. The light emitting module according to claim 19, wherein light emitting direction of the third light emitter is the same with that of the fourth light emitter.

23. The light emitting module according to claim 19, wherein light emitting direction of the third light emitter is different with that of the forth light emitter.

24. The light emitting module according to claim 22, wherein light emitting direction of the first light emitter is the same with that of the second light emitter.

25. The light emitting module according to claim 22, wherein light emitting direction of the first light emitter is different with that of the second light emitter.

26. The light emitting module according to claim 23, wherein light emitting direction of the first light emitter is different with that of the second light emitter.

27. An illumination device, comprising:
a plurality of the light emitting modules according to claim 1; and
at least one connecting unit electrically connected with the light emitting modules.

28. The illumination device according to claim 27, wherein the connecting unit comprises a welding member, a wire, a male and female connector or a latching structure.
